(19) United States
(12) Patent Application Publication
(10) Pub. No.: US 2011/0180722 A1
(43) Pub. Date: Jul. 28, 2011

(54) ALIGNING CHARGED PARTICLE BEAMS

(75) Inventor: Raymond Hill, Rowley, MA (US)

(73) Assignee: CARL ZEISS NTS, LLC, Peabody, MA (US)

(21) Appl. No.: 13/062,797

(22) PCT Filed: Aug. 12, 2009
(86) PCT No.: PCT/US09/53523

§ 371 Date: Mar. 31, 2011

Related U.S. Application Data
(60) Provisional application No. 61/101,197, filed on Sep. 30, 2008.

(51) Int. Cl. H01J 37/147

(52) U.S. Cl. 250/397; 250/396 R

(57) ABSTRACT

Disclosed are systems (2000) and a method for aligning a charged particle beam (2100) in charged particle optics that include a charged particle source (2010) and a charged particle optical column (2040), where at least one electrode (2050, 2060) of the column includes a plurality of segments, and where different electrical potentials are applied to at least some of the segments to correct for source (2010) till and/or displacement errors and to align particle beam (2100) a long axis (2045) of the column (2040). Alternatively, magnetic field-generating elements can be used for aligning.

### TECHNICAL FIELD

This disclosure relates to aligning charged particle beams in charged particle optics such as ion columns, as well as related components and systems.

### BACKGROUND

Aligning a charged particle beam with charged particle optics such as ion and/or electron columns can help ensure that the beam travels along a central axis of the optics.

### SUMMARY

In general, in a first aspect, the disclosure features a system that includes a charged particle source and a charged particle optical column including a plurality of electrodes, where a first electrode of the column is cylindrical and positioned closest to the charged particle source, and includes a plurality of segments, and where different electrical potentials are applied to at least some of the segments.

In another aspect, the disclosure features a system that includes a charged particle source and a charged particle optical column including a plurality of charged particle optical elements, where a first element of the column includes a first charged particle deflector, the first element being positioned closest to the charged particle source and including a plurality of field-generating segments, and where a second charged particle deflector is positioned adjacent to the first charged particle deflector, and includes a plurality of field-generating segments.

In a further aspect, the disclosure features a system that includes a charged particle source configured to generate a charged particle beam having a beam path, a first segmented element configured to generate a first variable field, and charged particle optics, where the first segmented element is between the charged particle source and the charged particle optics along the beam path.

In another aspect, the disclosure features a system that includes a charged particle source configured to generate a charged particle beam having a beam path, beam deflection means, and charged particle optics, where the beam deflection means is between the charged particle source and the charged particle optics along the beam path.

In a further aspect, the disclosure features a system that includes a gas field ion source configured to generate an ion beam and ion optics having an axis, the ion optics configured to direct the ion beam to a sample, where the system is configured so that, during use, the gas field ion source cannot move linearly relative to the axis of the ion optics.

In another aspect, the disclosure features a system that includes a gas field ion source configured to generate an ion beam and ion optics having an axis, the ion optics configured to direct the ion beam to a sample, where the system is configured so that, during use, the gas field ion source cannot tilt relative to the axis of the ion optics.

In a further aspect, the disclosure features a method that includes generating a charged particle beam using a charged particle source and aligning the charged particle beam with an axis of charged particle optics without moving the charged particle source.

In another aspect, the disclosure features a system that includes a charged particle source configured to generate a charged particle beam having a beam path, a member, and charged particle optics having an axis, where the member is configured to align the charged particle beam along the axis of the charged particle optics.

Embodiments can include one or more of the following features.

The system can include a second electrode positioned between the source and the column, the second electrode being cylindrical and including a plurality of segments. A second electrode of the column can be positioned adjacent to the first electrode, the second electrode being cylindrical and including a plurality of segments.

The system can include a third electrode positioned adjacent to the first electrode in the column, the third electrode being cylindrical and including a plurality of segments. Different electrical potentials can be applied to all of the segments. Different electrical potentials can be applied to the segments of each of the first and second electrodes.

During operation, the source can be configured to produce charged particles propagating along a first direction, and the first and second electrodes can be configured to direct the charged particles to propagate along a second direction different from the first direction.

The system can include a charged particle detector and an electronic processor, where during operation the electronic processor is configured to direct the detector to measure charged particles produced by the source, and to adjust electrical potentials applied to at least some of the segments of the first and second electrodes based on the measured particles. The electronic processor can be configured to adjust the electrical potentials to increase a charged particle current measured by the detector.

Each of the plurality of segments can be a radial segment. Each of the plurality of segments can have a common shape. The first electrode can include radial segments each having a common shape, and the second electrode can include radial segments each having a common shape. The radial segments of the first electrode can have a shape that is different from the shape of the radial segments of the second electrode.

The first electrode can include four segments. The first electrode can include at least eight segments. The second electrode can include four segments. The second electrode can include at least eight segments.

During operation, the charged particle source can be configured to produce particles that include noble gas ions. The noble gas ions can include helium ions. During operation, at least some of the segments of the first charged particle deflector can be configured to produce an electric field. During operation, at least some of the segments of the first charged particle deflector can be configured to produce a magnetic field. During operation, at least some of the segments of the second charged particle deflector can be configured to produce an electric field. During operation, at least some of the segments of the second charged particle deflector can be configured to produce a magnetic field. During operation, each of the segments of either the first or the second charged particle deflector can be configured to produce an electric field, and each of the segments of the other charged particle deflector can be configured to produce a magnetic field.

A magnitude of a particle deflection produced by the magnetic field can be the same as a magnitude of a particle deflection produced by the electric field. The segments of the first and second charged particle deflectors can be configured to produce electric and magnetic fields of opposite dispersion. The first and second charged particle deflectors can form a dispersionless charged particle deflection system.

The system can include a second element of the column adjacent to the first element, the second element including a third charged particle deflector that includes a plurality of field-generating segments. During operation, at least some of the segments of the third charged particle deflector can be configured to produce an electric field. During operation, at least some of the segments of the third charged particle deflector can be configured to produce a magnetic field. At least some of the segments of the first charged particle deflector can be configured to produce a first electric field, and at least some of the segments of the first charged particle deflector can be configured to produce a second electric field different from the first electric field. At least some of the segments of the first charged particle deflector can be configured to produce a first magnetic field, and at least some of the segments of the first charged particle deflector can be configured to produce a second magnetic field different from the first magnetic field. At least some of the segments of the second charged particle deflector can be configured to produce a first electric field, and at least some of the segments of the second charged particle deflector can be configured to produce a second electric field different from the first electric field. At least some of the segments of the second charged particle deflector can be configured to produce a first magnetic field, and at least some of the segments of the second charged particle deflector can be configured to produce a second magnetic field different from the first magnetic field.

During operation, the source can be configured to produce charged particles propagating along a first direction, and the first and second charged particle deflectors can be configured to direct the charged particles to propagate along a second direction different from the first direction.

The system can include a charged particle detector and an electronic processor, where during operation the electronic processor can be configured to direct the detector to measure charged particles produced by the source, and to adjust fields generated by at least some of the segments of the first and second particle deflectors based on the measured particles. The electronic processor can be configured to adjust the fields to increase a charged particle current measured by the detector.

Each of the segments of the first particle deflector can be positioned symmetrically about a center of the first particle deflector, and each of the segments of the second particle deflector can be positioned symmetrically about a center of the second particle deflector. Each of the segments of the first particle deflector can have a common shape, and each of the segments of the second particle deflector can have a common shape.

At least some of the segments of the first or second particle deflectors include electrodes. At least some of the segments of the first or second particle deflectors include coils.

The first particle deflector can include four segments. The first particle deflector can include at least eight segments. The second particle deflector can include four segments. The second particle deflector can include at least eight segments.

The system can include a second segmented element configured to generate a second variable field, the second segmented element being between the charged particle source and the charged particle optics along the beam path. The first segmented element can be an electrode. The first segment element can have at least three segments. The system can include an extractor between the charged particle source and the first segmented element.

The charged particle source can be an ion source. The charged particle source can be a gas field ion source. The charged particle source can be an electron source.

During use, the first segmented element can change the direction of charged particles generated by the charged particle source. During use, the first segmented element can direct charged particles generated by the charged particle source along an axis of the charged particle optics.

The charged particle optics can include a first lens and alignment deflectors. The charged particle optics can include an aperture. The charged particle optics can include an astigmatism corrector. The charged particle optics can include scanning deflectors. The charged particle optics can include a second lens.

The beam deflection means can include an electrode. The beam deflection means can have at least three segments. The system can include an extractor between the charged particle source and the beam deflection means.

The system can be configured so that, during use, the gas field ion source cannot tilt relative to the axis of the ion optics.

The charged particle beam can be aligned with the axis of the charged particle optics without tilting the charged particle source. The charged particle beam can be aligned with the axis of the charged particle optics without linearly moving the charged particle source.

The member can be a segmented element.

Various embodiments are described herein. It is to be understood that features of these embodiments may be combined with each other, individually or in various combinations.

Embodiments can include one or more of the following advantages.

The use of electric and/or magnetic field-generating elements to control the position and trajectory of the charged particle beam can eliminate mechanical translation and/or tilt mechanisms that would otherwise be coupled to the charged particle source and used to control the position and trajectory of the beam. Such mechanical mechanisms can be heavy, bulky and/or complicated to operate while simultaneously maintaining reduced pressure in a charged particle system. By eliminating such mechanical mechanisms, the operation of charged particle systems at reduced pressure can be considerably simplified.

By using multiple alignment elements, the charged particle beam can be aligned along a central axis of charged particle optics (e.g., a charged particle column) prior to entering the optics. As a result, the charged particle optical elements do not have to be reconfigured to account for changes in the charged particle beam's position and/or trajectory (e.g., when a new charged particle source is installed in the charged particle system). Instead, the configuration of the charged particle optics can be maintained, and the alignment of the particle beam adjusted via manipulation of the multiple alignment elements so that the particle beam passes through the charged particle optics along a suitable trajectory.

Alignment and/or re-alignment of a charged particle source with charged particle optics can be significantly faster using electric and/or magnetic field-generating elements than with mechanical alignment mechanisms. For example, from time to time, a charged particle source may need to be re-aligned with charged particle optics (e.g., due to long-term drift). Alternatively, or in addition, a newly-installed charged particle source may need to be aligned with charged particle optics. In embodiments in which only electric and/or magnetic fields of varying amplitudes are used to align the source with the optics, alignment can be significantly faster than in situations where a mechanical alignment mechanism, which translates and/or tilts the source, is used.

The alignment mechanisms disclosed herein can be implemented without mechanical parts that move during alignment of charged particle beams. As a result, vibrations within the charged particle systems can be significantly reduced, improving the long-term stability (and reducing the long-term drift) of the charged particle sources.

The details of one or more embodiments are set forth in the accompanying drawings and description. Other features and advantages will be apparent from the description, drawings, and claims.

### DESCRIPTION OF DRAWINGS

FIG. 1 is a schematic diagram showing a cross-sectional view of a portion of a charged particle system that includes field-generating particle beam alignment elements.

FIG. 2A is a schematic diagram showing a one-piece electrode.

FIG. 2B is a schematic diagram showing a segmented electrode.

FIG. 3A is a schematic diagram showing a charged particle source displaced from charged particle optics.

FIG. 3B is a schematic diagram showing a charged particle source tilted with respect to charged particle optics.

FIG. 4A is a schematic diagram showing alignment of a particle beam from a displaced source.

FIG. 4B is a schematic diagram showing alignment of a particle beam from a tilted source.

FIG. 5 is a schematic diagram showing electrical potentials applied to segments of a field-generating element.

FIG. 6 is a schematic diagram showing a cross-sectional view of a portion of a charged particle system that includes a segmented extractor.

FIG. 7 is a schematic diagram showing a magnetic field-generating particle beam alignment element.

FIG. 8 is a schematic diagram of an ion microscope system.

FIG. 9 is a schematic diagram of a gas field ion source.

FIG. 10 is a schematic diagram of a helium ion microscope system.

Like reference symbols in the various drawings indicate like elements.

### DETAILED DESCRIPTION

Alignment of charged particle beams in charged particle systems with respect to particle optics is important to ensure that the particle optics direct beams to their intended positions on samples, to ensure that the particle optics can properly focus the beams to a small and symmetric spot, and/or to ensure that various aberrations (e.g., defocusing, astigmatism, and other focusing and/or alignment errors) do not arise. Alignment may be involved when a new charged particle source is installed in a charged particle system, for example. Alternatively, or in addition, during operation of the charged particle system, periodic re-alignment of an operating charged particle source may be used to compensate for long-term source drift produced by mechanical fatigue, thermal drift, and/or mechanical vibrations in the system, for example. Mechanical mechanisms can be used to align charged particle beams with respect to particle optics. Typically, such mechanisms provide for both translation of a particle source with respect to the charged particle optics (e.g., translation or shift in a plane transverse to a propagation direction of the charged particle beam), and for tilt of the charged particle source with respect to a central axis of the charged particle optics. By controlling translation (e.g., position) and/or tilt of the charged particle source, the position and trajectory of the charged particle beam can be controlled. Alignment of the charged particle source may be undertaken, for example, when a new charged particle source is introduced into a charged particle system and/or some time after a charged particle source has been installed in a charged particle system (e.g., to re-align the charged particle source), and can include adjustment of either or both of the shift of the charged particle source and the tilt of the charged particle source.

Mechanical tilt and translation mechanisms are typically heavy to provide support and stability for charged particle sources. The mechanisms are usually coupled to electric motors which permit mechanical movement of mechanism components. The movement of the components and operation of the motors can, in some embodiments, lead to introduction of mechanical vibrations into charged particle systems. Such vibrations can adversely affect both the long- and short-term stability of the systems. Moreover, the charged particle systems are typically operated at significantly-reduced pressure (e.g., 10⁻⁶ Torr or less). Moving mechanical components within a reduced-pressure chamber—where the components are coupled to other components (e.g., motors) outside the chamber—can be a difficult task while maintaining the integrity of the reduced-pressure environment in the chamber. Movement of the components is typically relatively slow to prevent significant perturbation of other components of the charged particle systems; accordingly, alignment of charged particle sources can be a slow process.

The charged particle systems disclosed herein use electric and/or magnetic field-generating elements to align charged particle beams with charged particle optics (e.g., particle columns) either prior to, or just as the charged particle beams enter the optics. No mechanical movement of the charged particle source occurs during alignment. As a result, no additional vibrations are introduced into the charged particle systems. Further, by using field-generating elements, the position and/or trajectory of the charged particle beam with respect to the particle optics can be selected, so that reconfiguration of the particle optical elements to account for different sources and/or source drift is not required. That is, the configuration of the particle optical elements can remain relatively static during operation, ensuring both reproducible operation of the charged particle systems and reproducible results from various applications which use the charged particle beams produced by the systems.

This disclosure consists of two parts. The first part discusses systems and methods for aligning charged particle beams with respect to particle optics. The second part discusses ion beam sources and systems.

### Charged Particle Beam Alignment

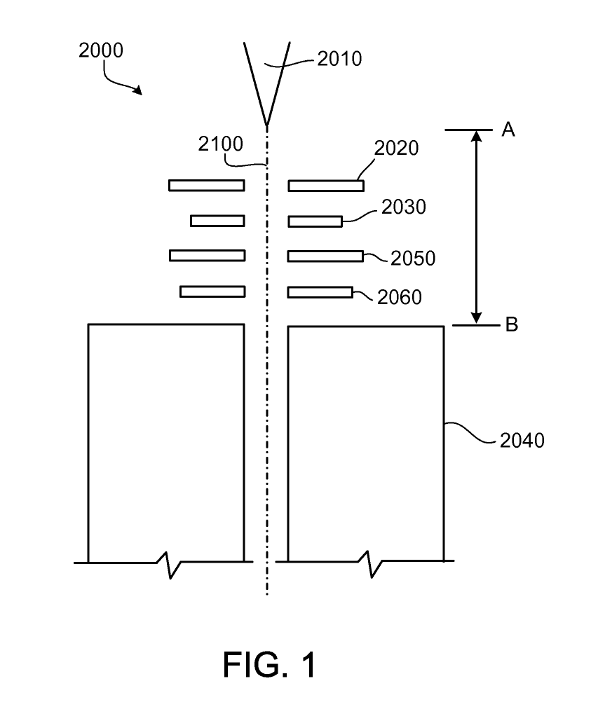

FIG. 1 is a schematic diagram showing a cross-sectional view of a portion of a charged particle system 2000 that includes field-generating elements configured to align a charged particle beam produced by system 2000 with respect to charged particle optical elements in system 2000. Charged particle system 2000 includes a tip 2010 that generates a beam 2100 of charged particles (e.g., ions such as noble gas ions, electrons). The charged particle beam 2100 passes through an extractor 2020 and an optional suppressor or field-shunt 2030. Before entering charged particle optics 2040 (e.g., a charged particle column), particle beam 2100 passes through field-generating elements 2050 and 2060. In the embodiment shown in FIG. 1, field-generating elements 2050 and 2060 are implemented as electrodes that generate electric fields to align the charged particles in beam 2100 with respect to a central axis 2045 of particle optics 2040. Further, in the embodiment shown in FIG. 1 and in the following discussion, suppressor 2030 is positioned between tip 2010 and charged particle optics 2040. In general, however, suppressor 2030 can be positioned either after tip 2010, as shown in FIG. 1, or before tip 2010. The discussion which follows applies to suppressor 2030 regardless of its position; that is, whether suppressor 2030 is positioned before or after tip 2010, suppressor 2030 can include a field-generating element formed of multiple field-generating segments.

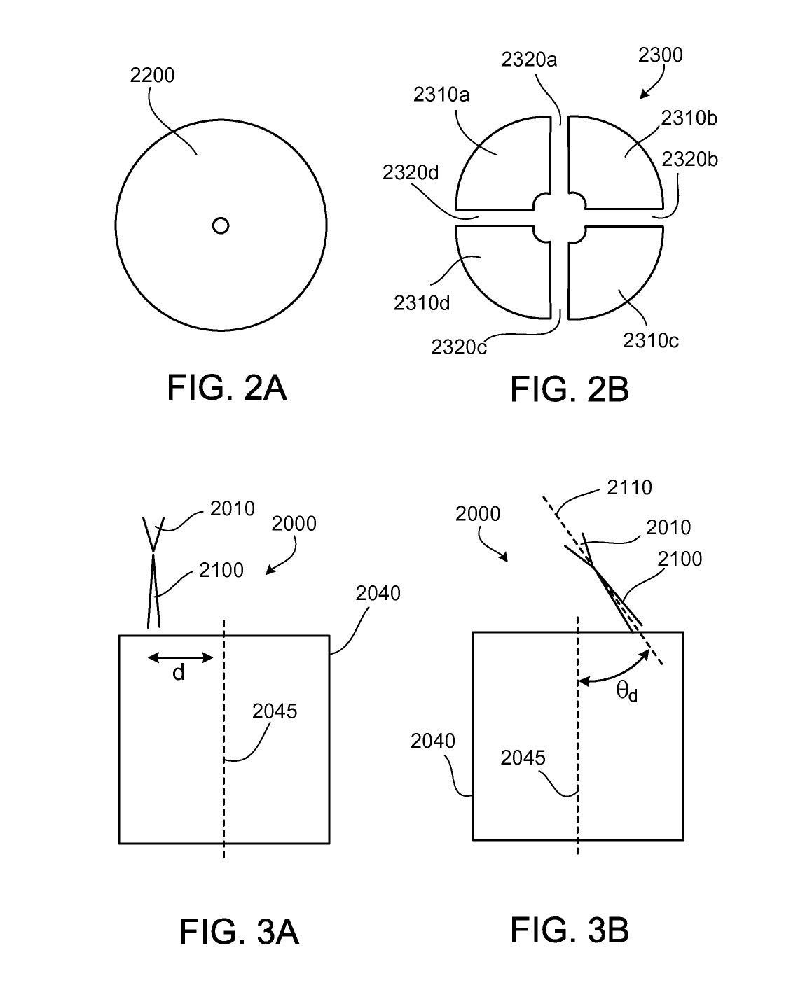

Each of field-generating elements 2050 and 2060 is implemented as a segmented electrode. FIG. 2A shows a schematic diagram of a conventional one-piece cylindrical electrode 2200. Typically, for example, particle optics 2040 can include a wide variety of electrodes such as electrode 2200 at different potentials, configured collectively to manipulate beam 2100 as it passes through particle optics 2040.

FIG. 2B shows a schematic diagram of a segmented electrode 2300. Segmented electrode 2300 includes four segments 2310a-d. Each segment corresponds roughly to a quarter-cylindrical shape, such that when the segments are arranged as in FIG. 2B, the overall shape of the assembled segments approximates the shape of electrode 2200, except that spaces 2320a-d separate the segments.

Each of field-generating elements 2050 and 2060 in FIG. 1 is implemented as a segmented electrode similar to electrode 2300 in FIG. 2B. During operation, different electrical potentials are applied to some (or all) of segments 2320a-d to generate an overall electric field that steers particle beam 2045 in a selected direction.

Typically, when tip 2010 (e.g., alone, or as part of a larger device that includes tip 2010) is introduced into system 2000, tip 2010 is not perfectly aligned with axis 2045 of particle optics 2040. The misalignment can take the form of a displacement of tip 2010 relative to axis 2045 (e.g., a displacement in a plane perpendicular to axis 2045) and/or a tilt of tip 2010 relative to axis 2045 (e.g., so that a non-zero angle is formed by a central axis of tip 2010 and axis 2045).

FIG. 3A shows an example of displacement between tip 2010 and axis 2045. In the portion of system 2000 shown in FIG. 3A, tip 2010 is displaced by an amount d relative to axis 2045 in a plane perpendicular to axis 2045. As a result, particle beam 2100 produced by tip 2010 is also displaced relative to axis 2045 by an amount d.

FIG. 3B shows an example of tip 2010 that is tilted relative to axis 2045. In FIG. 3B, a central axis 2110 of tip 2010 forms a non-zero angle θ_{d} with axis 2045. As a result of the tilt of tip 2010, particle beam 2100 propagates at the angle θ_{d} with respect to axis 2045.

As discussed above, each of the misalignment conditions shown in FIGS. 3A and 3B can lead to errors such as undesired displacement of particle beam 2100 on a sample, various particle beam aberrations such as defocusing and astigmatism, and even beam clipping and other aperture-related effects within particle optics 2040. Typically, both translation and tilt of a charged particle source may be present at the same time in system 2000, further complicating any alignment procedure.

By suitably configuring field-generating elements 2050 and 2060, both displacement errors and tilt errors can be compensated in system 2000 before particle beam 2100 enters particle optics 2040. Correction of these errors prior to beam 2100 entering optics 2040 can be important. For example, if beam 2100 is allowed to enter optics 2040 at a variety of positions and/or at a variety of angles, then various elements of optics 2040 may have to be re-configured to compensate for the differing particle positions and trajectories. However, if beam position and tilt errors can be compensated prior to beam 2100 entering particle optics 2040, then the various elements of optics 2040—which can be configured to work together in a complicated manner to manipulate beam 2100—can remain statically configured.

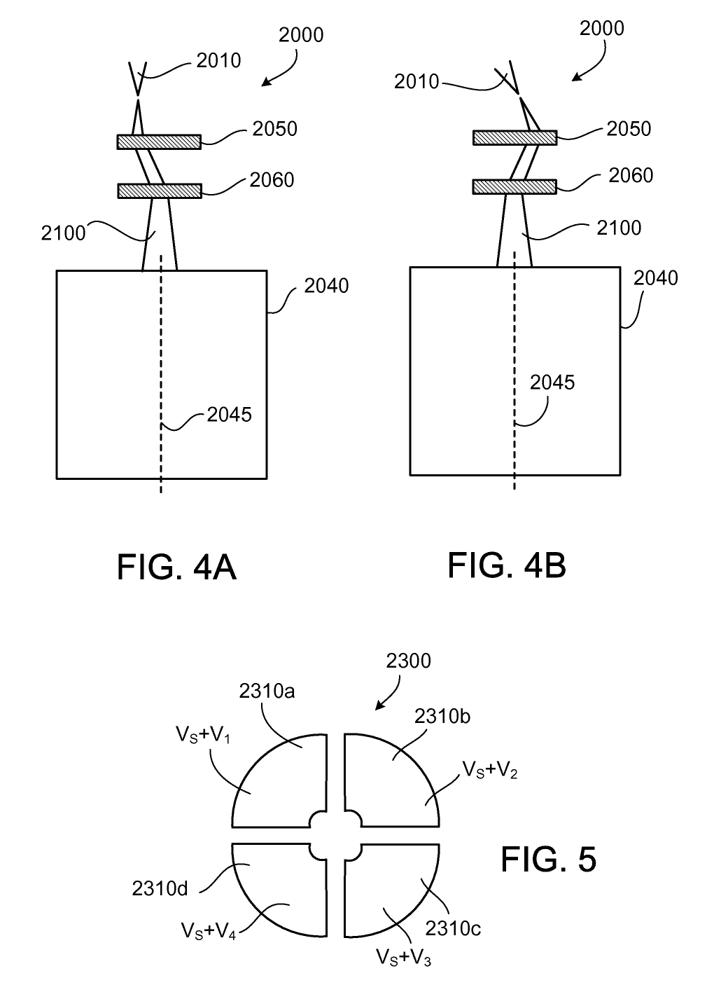

FIG. 4A is a schematic diagram showing a portion of charged particle system 2000 that includes field-generating elements 2050 and 2060 configured to correct for displacement errors. As shown in FIG. 4A, tip 2010 is displaced from axis 2045 of particle optics 2040 in a plane perpendicular to axis 2045. Particle beam 2100 emerges from tip 2010 also displaced from axis 2045 in the same perpendicular plane. However, beam 2100 passes through field-generating element 2050, which deflects beam 2100 toward axis 2045. Beam 2100 then passes through field-generating element 2060, which further deflects beam 2100 so that it's propagation direction coincides with axis 2045. Thus, as a result of the corrections applied by elements 2050 and 2060, beam 2100 enters and propagates through particle optics 2040 along the direction of axis 2045.

FIG. 4B is a schematic diagram showing the same portion of charged particle system 2000 as in FIG. 4A, with field-generating elements 2050 and 2060 configured to correct for tilt errors. As shown in FIG. 4B, tip 2010 is tilted relative to axis 2045 of particle optics 2040. Particle beam 2100 emerges from tip 2010 also tilted relative to axis 2045. However, beam 2100 passes through field-generating element 2050, which deflects beam 2100 toward axis 2045. Beam 2100 then passes through field-generating element 2060, which further deflects beam 2100 so that it's propagation direction coincides with axis 2045. As a result of the corrections applied by elements 2050 and 2060, beam 2100 enters and propagates through particle optics 2040 along the direction of axis 2045.

Elements 2050 and 2060 can also align a particle beam by correcting combined displacement and tilt errors. In general, both displacement and tilt produce errors manifest as position shifts of beam 2100 relative to axis 2045. The position shifts occur in planes transverse to axis 2045 (e.g., in two-dimensional planes). As a result, particle beam 2100 in system 2000 can include up to four error degrees of freedom. Each of field-generating elements 2050 and 2060 can be configured to displace beam 2100 in up to two directions (e.g., in a plane transverse to axis 2045). Accordingly, by using two such field-generating elements in system 2000, both tilt and displacement errors can be fully compensated. In some embodiments, if particle beam 2100 suffers from only one or two error degrees of freedom (e.g., only displacement errors, or only tilt errors), the errors can be compensated by a single field-generating element.

Accordingly, in certain embodiments, system 2000 includes only one field-generating element (e.g., either element 2050 or 2060 in FIG. 1).

Elements 2050 and 2060 can be configured to deflect particle beam 2100 by applying selected electric potentials to the various segments of these elements. By choosing suitable potentials, a particular electric field distribution can be formed in the central aperture of the electrodes. In some embodiments, for example, a relatively large static electrical potential Vₛ (e.g., from 1 to 50 kV) can be applied to each of the segments (e.g., 2310a-d) of a field-generating element (e.g., either element 2050 or 2060, or both elements 2050 and 2060). The larger static potential can be applied, for example, when element 2050 and/or 2060 functions as an extractor, a suppressor, or another type of element positioned between tip 2010 and particle optics 2040 (e.g., a charged particle column). In some embodiments, elements 2050 and/or 2060 can form portions of a first lens in particle optics 2040, and a large static potential Vs can be applied to the segments of elements 2050 and/or 2060.

Smaller electrical potentials can be further individually applied to each of the segments to create the particular electric field distribution in the central aperture of the element. For example, the total electrical potentials applied to each of segments 2310a-d can be Vₛ+V₁, Vₛ+V₂, Vₛ+V₃, and Vₛ+V₄, respectively. In some embodiments, for example, the sign of each of V₁, V₂, V₃, and V₄ can be positive or negative, and the magnitude of each of V₁, V₂, V₃, and V₄ can be from 1 V to 500 V (e.g., from 1 V to 400 V, from 1 V to 300 V, from 1 V to 200 V, from 1 V to 100 V, from 5 V to 75 V, from 10 V to 50 V). In certain embodiments, some (or all) of V₁, V₂, V₃, and V₄ can be different from one another. As an example, FIG. 5 shows a segmented electrode 2300 that includes four segments 2310a-d. Electrical potentials Vₛ+V₁, Vₛ+V₂, Vₛ+V₃, and Vₛ+V₄ are applied to the four segments of electrode 2300, respectively. If voltages V₁, V₂, V₃, and V₄ are selected such that V₁=−V₃ and V₂=−V₄, a deflection field is superimposed in the central aperture 2330 on the static field produced by common potential Vₛ which is applied to each of the segments.

In general, different field-generating elements in system 2000 can be configured to produce deflection fields having different amplitudes or the same amplitude, depending upon the extent of deflection required from each element to align particle beam 2100. Further, different field-generating elements can be configured to produce deflection fields in the same or different directions, depending upon the direction of the deflection required from each element to align particle beam 2100.

Typically, both field generating elements 2050 and 2060 are positioned between tip 2010 and particle optics 2040 in system 2000 (e.g., between positions A and B in FIG. 1). In FIG. 1, elements 2050 and 2060 are each positioned between suppressor 2030 and particle optics 2040. More generally, however, elements 2050 and 2060 can be positioned anywhere between tip 2010 and particle optics 2040 in system 2000. For example, in some embodiments, element 2050 can be positioned between extractor 2020 and element 2060 can be positioned after extractor 2020 (e.g., either between extractor 2020 and suppressor 2030 or between suppressor 2030 and particle optics 2040). Many different combinations of positions of elements 2050 and 2060 are possible, depending upon the interior geometrical constraints of system 2000, the properties of the particles in beam 2100 (e.g., the distribution of particle velocities and the nature of the particles), and the function of other components (e.g., extractor 2020, suppressor 2030) in system 2000.

In certain embodiments, one or more particle optics can be implemented as field-generating elements. For example, in FIG. 1, extractor 2020 can be implemented as a segmented electrode. That is, extractor 2020 can be configured to perform multiple functions: first, extractor 2020 can be configured (e.g., by applying a large static voltage Vₛ to each segment of extractor 2020) to function as an extractor. Further configuration of extractor 2020 by applying smaller voltages V₁-V₄ to each of its four segments permits extractor 2020 to function as a beam deflector in the manner shown in FIGS. 4A-B. As a result, to fully correct for both tilt errors and displacement errors, only one other segmented electrode may be present in system 2000. As discussed above, the additional segmented electrode can be positioned at many different locations within system 2000.

In some embodiments, the field-generating elements 2050 and/or 2060 can include fewer than four segments or more than four segments. In general, any of the field-generating elements in system 2000 can include two or more segments (e.g., three or more segments, four or more segments, five or more segments, six or more segments, seven or more segments, eight or more segments, nine or more segments, ten or more segments, or even more segments). Generally, additional segments are provided so that finer control over deflection of particle beam 2100 by the segments can be achieved. Further, by using additional segments, the homogeneity of the overall deflection field generated by the elements can be increased. For example, a field-generating element that includes eight segments can typically be used to produce a deflecting field that more closely approaches a unidirectional field than a similar field produced by a four-segment element. Moreover, field-generating elements with more than four segments can be used to produce more complex deflection fields than the fields that can be produced with four-segment elements. As a result, elements with more than four segments can be used to correct complex beam alignment errors.

The segments can each have the same (or approximately the same) shape (e.g., radial segments, as in FIG. 5), or some of the segments can have shapes that differ from the shapes of other segments. Typically, as shown in FIG. 5, the segments are symmetrically arranged about central aperture 2330. More generally, however, the segments can be symmetrically or asymmetrically arranged about aperture 2330, depending upon the overall design of the particle optics in system 2000 and/or the type and geometry of alignment that the field-generating elements are designed to perform. Further, the overall cross-sectional shape of the field-generating element, including its arrangement of segments, can be circular as shown in. FIG. 5, or another shape (e.g., square, rectangular, ellipsoid, triangular, hexagonal, octagonal, or another regular or irregular shape).

In certain embodiments, system 2000 can include more than two field-generating elements. Additional field-generating elements can be used to provide additional control over the position and trajectory of beam 2100, for example. In general, system 2000 can include one or more field-generating elements (e.g., two or more field-generating elements, three or more field-generating elements, four or more field-generating elements, five or more field-generating elements, six or more field-generating elements, eight or more field-generating elements).

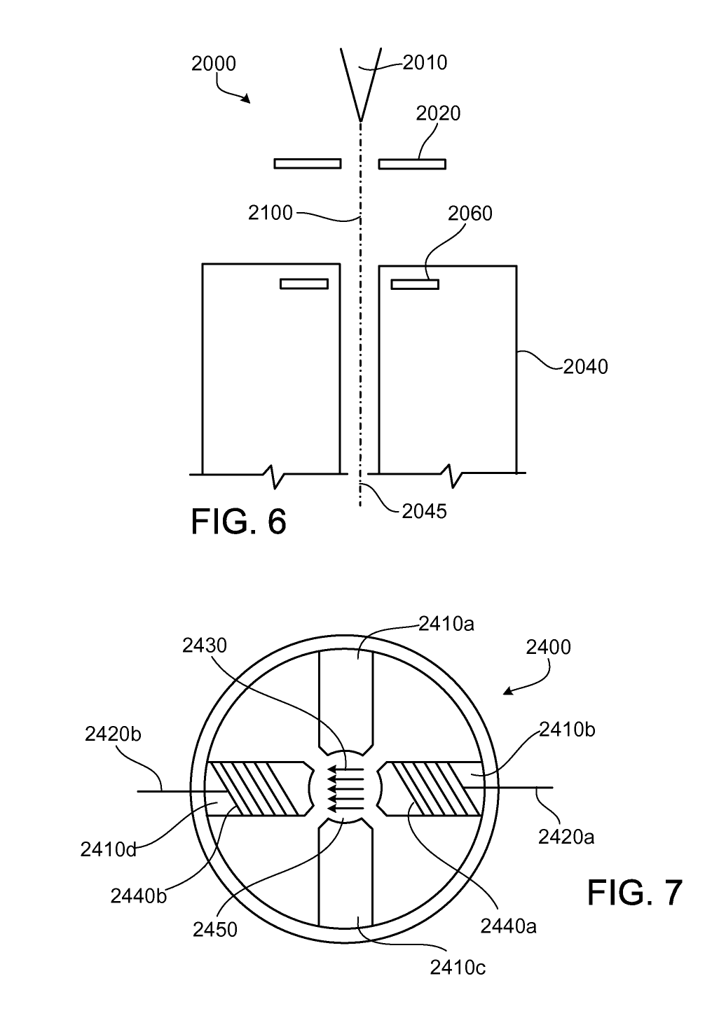

In some embodiments, one or more of the field-generating elements can form a part of a first lens of particle optics 2040. FIG. 6 shows an embodiment of charged particle system 2000 where extractor 2020 is implemented as a field-generating element. Further, a second field-generating element 2060 forms a portion of a first lens of particle optics 2040. The other components of system 2000 in FIG. 6 typically function in a similar manner to the components shown in FIG. 1, for example. The two field-generating elements—extractor 2020 and element 2060—are configured to correct for displacement and tilt errors of tip 2010, thereby aligning particle beam 2100 with axis 2045 of particle optics 2040.

In general, a wide variety of different configurations are possible when one or more field-generating elements form portions of lenses in particle optics 2040. In some embodiments, for example, both the first and second electrodes of the first lens in particle optics 2040 can be formed as field-generating elements. By suitably configuring these elements (e.g., by applying suitable electrical potentials to the segments of these elements), displacement and tilt errors of tip 2010 can be corrected, and particle beam 2100 can be aligned such that it propagates along axis 2045 through the remainder of particle optics 2040.

In certain embodiments, the extractor, and each of the first and second electrodes of the first lens in particle optics 2040 can be formed as field-generating elements. As above, by suitably configuring these elements, displacement and tilt errors of tip 2010 can be corrected, and particle beam 2100 can be aligned so that it propagates along axis 2045 through the remainder of particle optics 2040. The extra field-generating element provides additional flexibility in aligning the particle beam.

In some embodiments, the field-generating elements can be configured to produce magnetic fields rather than electric fields to deflect charged particles. FIG. 7 shows an embodiment of a field-generating element 2400 that includes four segments 2410a-d. Each of the four segments is formed of a magnetic material of high permeability such as a nickel-iron alloy. Each segment is typically surrounded by a helical coil winding (in FIG. 7, windings 2440a and 2440b are shown surrounding only segments 2410b and 2410d for clarity). During operation, electrical current is supplied to the coil windings (e.g., via one or more of wires 2420a and 2420b) to generate a magnetic field in the windings, which permeates into the segments. The magnetic fields penetrate from one segment to another, so that with suitably configured segments, a relatively uniform magnetic deflection field 2430 can be formed in the central aperture 2450 of the element. Although not shown in FIG. 7, a similar deflection field can be generated between segments 2410a and 2410c in aperture 2450, to provide for deflection of particle beam 2100 a direction orthogonal to the deflection direction of magnetic field 2430. Typically, the strength of the magnetic fields generated by segments 2410a-d can be varied by changing the current through the windings surrounding each segment.

In general, field-generating elements that generate magnetic fields for particle beam deflection can be used in place of any of the electric field-generating elements discussed above. Magnetic field-generating elements can typically have any of the properties discussed above in connection with electric field-generating elements. For example, magnetic field-generating elements can include two or more segments, and the two or more segment shapes can all be the same, or different. Segment shapes can be regular or irregular, and the segments can be arranged about the central aperture 2450 in either a symmetrical or asymmetrical manner. Any number of magnetic field-generating elements can be used to suitably correct for source tilt and/or displacement errors and to align particle beam 2100 along axis 2045 of particle optics 2040. Further, magnetic field-generating elements can typically be positioned anywhere between tip 2010 and particle optics 2040. In some embodiments, the first lens of particle optics 2040 can include one or more magnetic field-generating elements, as discussed above in connection with electric field-generating elements.

In some embodiments, combinations of electric and magnetic field-generating elements can be used to correct for source tilt and displacements errors and to align particle beam 2100 with axis 2045 of particle optics 2040. In particular, combinations of electric and magnetic field-generating elements can be used to yield dispersionless systems. Magnetic fields are generally half as dispersive with respect to charged particles as electric fields. Further, magnetic fields disperse charged particles in a manner opposite to the manner in which electric fields disperse charged particles; that is, the dispersion produced by magnetic fields is opposite in sign to the dispersion produced by electric fields. Accordingly, by using both electric and magnetic field-generating elements in system 2000 and suitably choosing the amplitudes of the fields generated by each of these elements, dispersionless alignment of particle beam 2100 with axis 2045 of particle optics 2040 can be achieved. For example, through suitable configuration, the electric and magnetic field-generating elements can be configured to generate particle deflections that are opposite to one another in both magnitude and direction.

In certain embodiments, electric and/or magnetic field-generating elements can be configured in automated fashion by system 2000. For example, system 2000 can include an electronic processor that is coupled to one or more voltage and/or current sources that supply voltage and/or current to the field-generating elements. The electronic processor can be coupled to a detector that measures particle beam 2100 after it emerges from particle optics 2040, for example, and adjusts one or more of the field-generating elements based on the measured beam. As an example, the detector can be configured to measure a particle current in the beam, and the electronic processor can be configured to adjust one or more of the field-generating elements to increase the measured current of the particle beam.

The field-generating elements disclosed herein can be used to align a wide variety of different types of particle beams. The particle beams can include, for example, electrons and/or ions. In particular, in some embodiments, the particle beams can include noble gas ions such as helium ions, neon ions, argon ions, and/or krypton ions. One or more of these types of ions can be generated in ion beam systems such as gas field ion systems, which are discussed in the second part of this disclosure. The systems disclosed herein can also be used to align charged particle beams that include other types of ions such as hydrogen ions, for example.

While embodiments have been described in which field-generating elements are used in systems that do not include mechanical mechanisms for beam alignment, optionally a system can include field-generating elements and a mechanical mechanism for beam alignment. Examples of such mechanical mechanisms are disclosed, for example, in U.S. Patent Application Publication No. US 2007/0158558, the entire contents of which are incorporated herein by reference.

### Ion Beam Systems

This part of the disclosure relates to systems and methods for producing ion beams, and detecting particles including secondary electrons and scattered ions that leave a sample of interest (e.g., a semiconductor device that includes various circuit elements) due to exposure of the sample to an ion beam. The systems and methods can be used to obtain one or more images of the sample, for example.

Typically, gas ion beams that are used to interrogate samples are produced in multipurpose microscope systems. Microscope systems that use a gas field ion source to generate ions that can be used in sample analysis (e.g., imaging) are referred to as gas field ion microscopes. A gas field ion source is a device that includes a tip (typically having an apex with 10 or fewer atoms) that can be used to ionize neutral gas species to generate ions (e.g., in the form of an ion beam) by bringing the neutral gas species into the vicinity of the tip (e.g., within a distance of about four to five angstroms) while applying a high positive potential (e.g., one kV or more relative to the extractor (see discussion below)) to the apex of the tip.

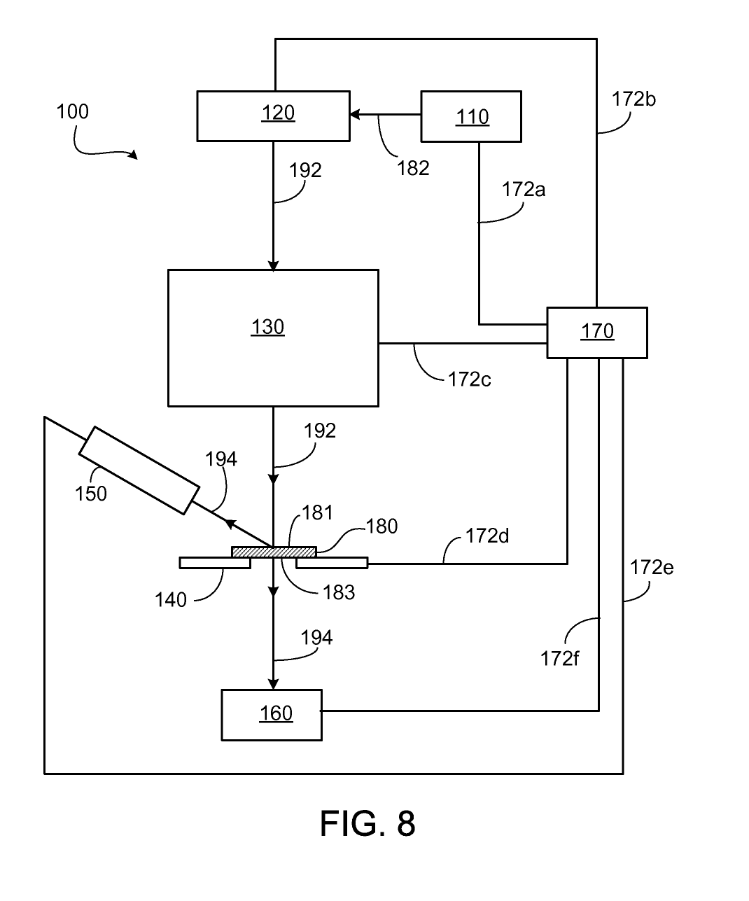

FIG. 8 shows a schematic diagram of a gas field ion microscope system 100 that includes a gas source 110, a gas field ion source 120, ion optics 130, a sample manipulator 140, a front-side detector 150, a back-side detector 160, and an electronic control system 170 (e.g., an electronic processor, such as a computer) electrically connected to various components of system 100 via communication lines 172a-172f. A sample 180 is positioned in/on sample manipulator 140 between ion optics 130 and detectors 150, 160. During use, an ion beam 192 is directed through ion optics 130 to a surface 181 of sample 180, and particles 194 resulting from the interaction of ion beam 192 with sample 180 are measured by detectors 150 and/or 160.

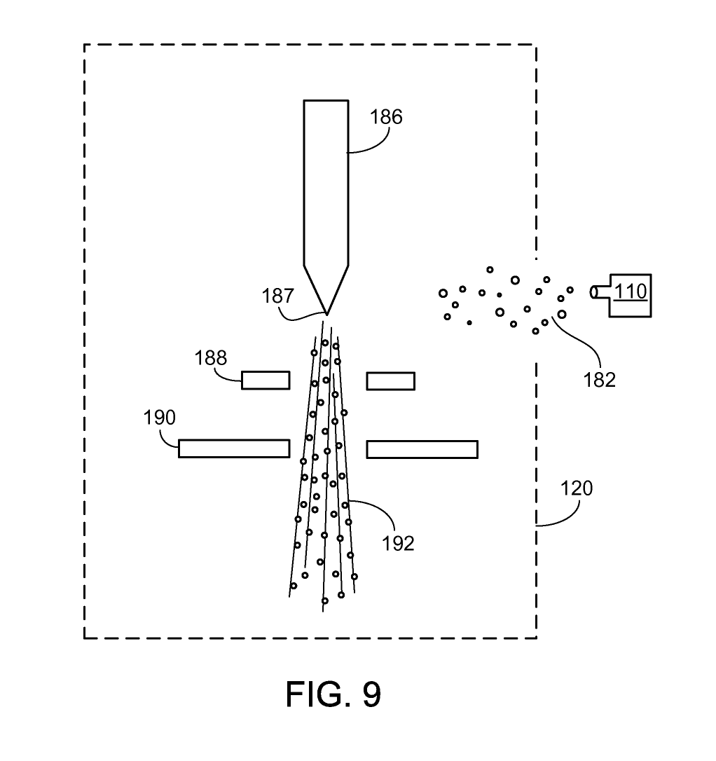

As shown in FIG. 9, gas source 110 is configured to supply one or more gases 182 to gas field ion source 120. Gas source 110 can be configured to supply the gas(es) at a variety of purities, flow rates, pressures, and temperatures. In general, at least one of the gases supplied by gas source 110 is a noble gas (helium (He), neon (Ne), argon (Ar), krypton (Kr), xenon (Xe)), and ions of the noble gas are desirably the primary constituent in ion beam 192.

Optionally, gas source 110 can supply one or more gases in addition to the noble gas(es); an example of such a gas is nitrogen. Typically, while the additional gas(es) can be present at levels above the level of impurities in the noble gas(es), the additional gas(es) still constitute minority components of the overall gas mixture introduced by gas source 110.

Gas field ion source 120 is configured to receive the one or more gases 182 from gas source 110 and to produce gas ions from gas(es) 182. Gas field ion source 120 includes a tip 186 with a tip apex 187, an extractor 190 and optionally a suppressor 188.

Tip 186 can be formed of various materials. In some embodiments, tip 186 is formed of a metal (e.g., tungsten (W), tantalum (Ta), iridium (Ir), rhenium (Rh), niobium (Nb), platinum (Pt), molybdenum (Mo)). In certain embodiments, tip 186 can be formed of an alloy. In some embodiments, tip 186 can be formed of a different material (e.g., carbon (C)).

During use, tip 186 is biased positively (e.g., approximately 20 kV) with respect to extractor 190, extractor 190 is negatively or positively biased (e.g., from −20 kV to +50 kV) with respect to an external ground, and optional suppressor 188 is biased positively or negatively (e.g., from −5 kV to +5 kV) with respect to tip 186. Because tip 186 is typically formed of an electrically conductive material, the electric field of tip 186 at tip apex 187 points outward from the surface of tip apex 187. Due to the shape of tip 186, the electric field is strongest in the vicinity of tip apex 187. The strength of the electric field of tip 186 can be adjusted, for example, by changing the positive voltage applied to tip 186. With this configuration, un-ionized gas atoms 182 supplied by gas source 110 are ionized and become positively-charged ions in the vicinity of tip apex 187. The positively-charged ions are simultaneously repelled by positively charged tip 186 and attracted by negatively charged extractor 190 such that the positively-charged ions are directed from tip 186 into ion optics 130 as ion beam 192. Suppressor 188 assists in controlling the overall electric field between tip 186 and extractor 190 and, therefore, the trajectories of the positively-charged ions from tip 186 to ion optics 130. In general, the overall electric field between tip 186 and extractor 190 can be adjusted to control the rate at which positively-charged ions are produced at tip apex 187, and the efficiency with which the positively-charged ions are transported from tip 186 to ion optics 130.

In general, ion optics 130 are configured to direct ion beam 192 onto surface 181 of sample 180. Ion optics 130 can, for example, focus, collimate, deflect, accelerate, and/or decelerate ions in beam 192. Ion optics 130 can also allow only a portion of the ions in ion beam 192 to pass through ion optics 130. Generally, ion optics 130 include a variety of electrostatic and other ion optical elements that are configured as desired. By manipulating the electric field strengths of one or more components (e.g., electrostatic deflectors) in ion optics 130, ion beam 192 can be scanned across surface 181 of sample 180. For example, ion optics 130 can include two deflectors that deflect ion beam 192 in two orthogonal directions. The deflectors can have varying electric field strengths such that ion beam 192 is rastered across a region of surface 181.

When ion beam 192 impinges on sample 180, a variety of different types of particles 194 can be produced. These particles include, for example, secondary electrons, Auger electrons, secondary ions, secondary neutral particles, primary neutral particles, scattered ions and photons (e.g., X-ray photons, IR photons, visible photons, UV photons). Detectors 150 and 160 are positioned and configured to each measure one or more different types of particles resulting from the interaction between ion beam 192 and sample 180. As shown in FIG. 9, detector 150 is positioned to detect particles 194 that originate primarily from surface 181 of sample 180, and detector 160 is positioned to detect particles 194 that emerge primarily from surface 183 of sample 180 (e.g., transmitted particles). In general, any number and configuration of detectors can be used in the microscope systems disclosed herein. In some embodiments, multiple detectors are used, and some of the multiple detectors are configured to measure different types of particles. In certain embodiments, the detectors are configured to provide different information about the same type of particle (e.g., energy of a particle, angular distribution of a given particle, total abundance of a given particle). Optionally, combinations of such detector arrangements can be used.

In general, the information measured by the detectors is used to determine information about sample 180. Typically, this information is determined by obtaining one or more images of sample 180. By rastering ion beam 192 across surface 181, pixel-by-pixel information about sample 180 can be obtained in discrete steps. Detectors 150 and/or 160 can be configured to detect one or more different types of particles 194 at each pixel.

The operation of microscope system 100 is typically controlled via electronic control system 170. For example, electronic control system 170 can be configured to control the gas(es) supplied by gas source 110, the temperature of tip 186, the electrical potential of tip 186, the electrical potential of extractor 190, the electrical potential of suppressor 188, the settings of the components of ion optics 130, the position of sample manipulator 140, and/or the location and settings of detectors 150 and 160. Optionally, one or more of these parameters may be manually controlled (e.g., via a user interface integral with electronic control system 170). Additionally or alternatively, electronic control system 170 can be used (e.g., via an electronic processor, such as a computer) to analyze the information collected by detectors 150 and 160 and to provide information about sample 180 (e.g., topography information, material constituent information, crystalline information, voltage contrast information, optical property information, magnetic information), which can optionally be in the form of an image, a graph, a table, a spreadsheet, or the like. Typically, electronic control system 170 includes a user interface that features a display or other kind of output device, an input device, and a storage medium.

In some embodiments, electronic control system 170 can be configured to control additional devices. For example, electronic control system 170 can be configured to adjust electrical potentials and/or electrical currents supplied to segments of field-generating particle alignment elements (e.g., shown in FIG. 1). Electronic control system 170 can be coupled to a detector (e.g., detector 150 and/or 160 and/or another detector) and configured to measure one or more properties of ion beam 192, such as an ion beam current. Based on the measured ion beam current, electronic control system 170 can be configured to adjust the electrical potentials and/or currents applied to the segments of the field-generating elements (e.g., to increase the measured ion beam current).

Detectors 150 and 160 are depicted schematically in FIG. 9, with detector 150 positioned to detect particles from surface 181 of sample 180 (the surface on which the ion beam impinges), and detector 160 positioned to detect particles from surface 183 of sample 180. In general, a wide variety of different detectors can be employed in microscope system 200 to detect different particles, and microscope system 200 can typically include any desired number of detectors. The configuration of the various detector(s) can be selected in accordance with particles to be measured and the measurement conditions. In some embodiments, a spectrally resolved detector can be used. Such detectors are capable of detecting particles of different energy and/or wavelength, and resolving the particles based on the energy and/or wavelength of each detected particle.

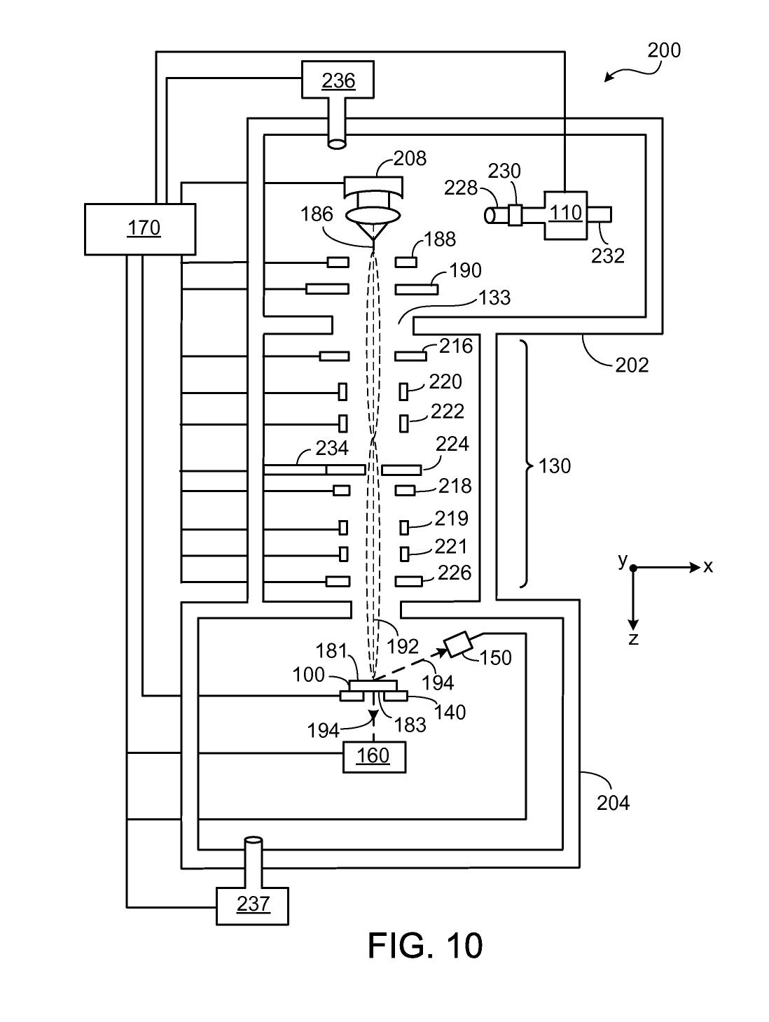

FIG. 10 is a schematic diagram of a helium ion microscope system 200. As shown in FIG. 10, in some embodiments, ion optics 130 include a first lens 216, alignment deflectors 220 and 222, an aperture 224, an astigmatism corrector 218, scanning deflectors 219 and 221, and a second lens 226. Aperture 224 is positioned in an aperture mount 234. Sample 180 is mounted in/on a sample manipulator 140 within second vacuum housing 204. Detectors 150 and 160, also positioned within second vacuum housing 204, are configured to detect particles 194 from sample 180. Gas source 110, tip manipulator 208, extractor 190, suppressor 188, first lens 216, alignment deflectors 220 and 222, aperture mount 234, astigmatism corrector 218, scanning deflectors 219 and 221, sample manipulator 140, and/or detectors 150 and/or 160 are typically controlled by electronic control system 170. Optionally, electronic control system 170 also controls vacuum pumps 236 and 237, which are configured to provide reduced-pressure environments inside vacuum housings 202 and 204, and within ion optics 130.

In some embodiments, aperture 224 can be positioned to allow substanially only ions from one atom of tip 186 to pass through the aperture. For example, tip 186 can include a relatively small number of atoms (e.g., three atoms) that form a terminal shelf. Aperture 224 can be positioned so that substantially only ions generated in the vicinity of one of the terminal shelf atoms can pass through the aperture.

In some embodiments, alignment of the charged particle beam through charged particle optics can be performed in two stages. In a first procedure, performed with aperture 224 withdrawn from the path of the beam, the beam is aligned with the central axis of the charged particle optics, as discussed above. A second alignment procedure can then be performed to ensure that He ions generated via the interaction of He gas atoms with the three-atom shelf at apex 187 of tip 186 pass through aperture 224. The electrical potentials applied to deflectors 220 and 222 are adjusted so that 70% or more (e.g., 75% or more, 80% or more, 85% or more, 90% or more, 95% or more, 97% or more, 99% or more) of the He ions in ion beam 192 that pass through aperture 224 are generated via the interaction of He gas atoms with only one of the three trimer atoms at the apex of tip 186. At the same time, the adjustment of the potentials applied to deflectors 220 and 222 ensures that aperture 224 prevents 50% or more (e.g., 60% or more, 70% or more, 80% or more, 90% or more, 95% or more, 98% or more) of the He ions in ion beam 192 generated by the interaction of He gas atoms with the other two trimer atoms from reaching surface 181 of sample 180. As a result of this second alignment procedure, the He ion beam that passes through aperture 224 and exits ion optics 130 includes He atoms that were ionized primarily in the vicinity of only one of the three trimer atoms at the apex of tip 186.

Ion beam systems and methods are generally disclosed, for example, in U.S. Patent Application Publication No. US 2007/0158558.

### Computer Hardware and Software

In general, any of the methods described above can be implemented and/or controlled in computer hardware or software, or a combination of both. The methods can be implemented in computer programs using standard programming techniques following the methods and figures described herein. Program code is applied to input data to perform the functions described herein and generate output information. The output information is applied to one or more output devices such as a display monitor. Each program may be implemented in a high level procedural or object oriented programming language to communicate with a computer system. However, the programs can be implemented in assembly or machine language, if desired. In any case, the language can be a compiled or interpreted language. Moreover, the program can run on dedicated integrated circuits preprogrammed for that purpose.

Each such computer program is preferably stored on a storage medium or device (e.g., ROM or magnetic diskette) readable by a general or special purpose programmable computer, for configuring and operating the computer when the storage media or device is read by the computer to perform the procedures described herein. The computer program can also reside in cache or main memory during program execution. The methods or portions thereof can also be implemented as a computer-readable storage medium, configured with a computer program, where the storage medium so configured causes a computer to operate in a specific and predefined manner to perform the functions described herein.

Other embodiments are in the claims.

1-24. (canceled)

25. A system, comprising:
a charged particle source;
a charged particle optical column comprising a plurality of electrodes, a first electrode of the charged particle optical column is cylindrical and positioned closest to the charged particle source, the first electrode comprising a plurality of segments; and
a second electrode positioned between the charged particle source and the charged particle optical column, the second electrode being cylindrical and comprising a plurality of segments,
wherein different electrical potentials are applied to at least some of the segments.

26. The system of claim 25, further comprising a third electrode positioned adjacent to the first electrode in the charged particle optical column, the third electrode being cylindrical and comprising a plurality of segments.

27. The system of claim 25, wherein different electrical potentials are applied to all of the segments of each of the first and second electrodes.

28. The system of claim 25, wherein different electrical potentials are applied to the segments of each of the first and second electrodes.

29. The system of claim 25, wherein during operation, the source is configured to produce charged particles propagating along a first direction, and the first and second electrodes are configured to direct the charged particles to propagate along a second direction different from the first direction.

30. The system of claim 25, further comprising a charged particle detector and an electronic processor, wherein during operation the electronic processor is configured to direct the detector to measure charged particles produced by the charged particle source, and to adjust electrical potentials applied to at least some of the segments of the first and second electrodes based on the measured particles.

31. The system of claim 30, wherein the electronic processor is configured to adjust the electrical potentials to increase a charged particle current measured by the detector.

32. The system of claim 25, wherein each of the plurality of segments of the first electrode is a radial segment.

33. The system of claim 32, wherein each of the plurality of segments of the first electrode has a common shape.

34. The system of claim 25, wherein the first electrode comprises radial segments each having a common shape, and wherein the second electrode comprises radial segments each having a common shape.

35. The system of claim 34, wherein the radial segments of the first electrode have a shape that is different from the shape of the radial segments of the second electrode.

36. The system of claim 25, wherein the first electrode comprises four segments.

37. The system of claim 25, wherein the first electrode comprises at least eight segments.

38. The system of claim 25, wherein the second electrode comprises four segments.

39. The system of claim 25, wherein the second electrode comprises at least eight segments.

40. A system, comprising:
a charged particle source; and
a charged particle optical column comprising a plurality of charged particle optical elements, a first element of the charged particle column comprising a first charged particle deflector, the first element being positioned closest to the charged particle source and comprising a plurality of field-generating segments; and
wherein a second charged particle deflector is positioned between the charged particle source and the charged particle optical column, the second charged particle deflector comprising a plurality of field-generating segments.

41. A system, comprising:
a charged particle source;
a charged particle optical column comprising a plurality of electrodes, including a first electrode positioned closest to the charged particle source, the first electrode comprising a plurality of segments;
a charged particle detector; and
an electronic processor,
wherein, during operation the electronic processor is configured to direct the detector to measure charged particles produced by the charged particle source, and to adjust electrical potentials applied to each of the segments of the first electrode based on the measured particles so that the electrical potential applied to each segment of the first electrode is independent of the electrical potentials applied to the other segments of the first electrode.

42. The system of claim 41, further comprising a second electrode positioned between the charged particle source and the charged particle optical column, wherein the second electrode is cylindrical and comprises a plurality of segments.

43. The system of claim 42, further comprising a third electrode positioned adjacent to the first electrode in the charged particle optical column, wherein the third electrode is cylindrical and comprises a plurality of segments.

44. The system of claim 42, wherein during operation, the source is configured to produce charged particles propagating along a first direction, and the first and second electrodes are configured to direct the charged particles to propagate along a second direction different from the first direction.
